(19) United States
(12) Patent Application Publication
(10) Pub. No.: US 2012/0045854 A1
(43) Pub. Date: Feb. 23, 2012

(54) INSPECTING METHOD, TEMPLATE MANUFACTURING METHOD, SEMICONDUCTOR INTEGRATED CIRCUIT MANUFACTURING METHOD, AND INSPECTING SYSTEM

(76) Inventors: Yasuo Matsuoka, Kanagawa (JP); Ryoichi Inanami, Kanagawa (JP)

(21) Appl. No.: 13/208,605

(22) Filed: Aug. 12, 2011

(30) Foreign Application Priority Data
Aug. 23, 2010 (JP) 2010-186044

(51) Int. Cl. H01L 21/66; G06F 17/50

(52) U.S. Cl. 438/16; 716/52; 257/E21.53

(57) ABSTRACT

According to one embodiment, a template for manufacturing a memory cell array comprising a relievable area and a redundant area replaceable with the relievable area is to be inspected. First, based on a defect position of a defect-detected template and position information on a relievable area, a decision is made as to whether the detected defect is positioned within the relievable area. A decision is made as to whether the number of defect-detected relievable areas exceeds the preset permissible number. When the detected defect is positioned outside the relievable area or when the number of defect-detected relievable areas exceeds the permissible number, a notification that the template has failed the inspection is output.

### CROSS-REFERENCE TO RELATED APPLICATIONS

This application is based upon and claims the benefit of priority from the prior Japanese Patent Application No. 2010-186044, filed on Aug. 23, 2010; the entire contents of which are incorporated herein by reference.

### FIELD

Embodiments described herein relate generally to an inspecting method, a template manufacturing method, a semiconductor integrated circuit manufacturing method and an inspecting system.

### BACKGROUND

A nanoimprint lithography technique (which will be simply referred to as nanoimprinting) is known as a semiconductor integrated circuit manufacturing technique. The nanoimprinting is a technique for pressing a template on which a pattern of a semiconductor integrated circuit is formed onto a resist applied to a semiconductor wafer thereby to transfer the pattern formed on the template onto the resist. By use of the nanoimprinting, a nanometer-sized pattern can be transferred with a higher resolution than by use of an optical lithography technique.

However, there is a problem that since a template has a fine structure equivalent to a semiconductor integrated circuit to be manufactured, a defect-free template is not easy to manufacture and it costs too much to manufacture the template.

### BRIEF DESCRIPTION OF THE DRAWINGS

FIG. 1 is a diagram for explaining an exemplary structure of an inspecting system according to a first embodiment;

FIG. 2 is a diagram showing an exemplary template pattern;

FIG. 3 is diagrams for explaining an exemplary correspondence of relievable areas between layers;

FIG. 4 is a diagram for explaining a functional structure of the inspecting system according to the first embodiment;

FIG. 5 is a flowchart for explaining a template manufacturing method according to the first embodiment;

FIG. 6 is a flowchart for explaining a template manufacturing method according to a second embodiment;

FIG. 7 is a flowchart for explaining child template manufacturing steps;

FIG. 8 is a diagram for explaining various areas of a parent template and a child template;

FIG. 9 is a diagram for explaining parts set as relief areas (non-inspection areas);

FIG. 10 is a diagram for explaining a functional structure of an inspecting system according to a third embodiment; and

FIG. 11 is a flowchart for explaining a semiconductor integrated circuit manufacturing method according to the third embodiment.

### DETAILED DESCRIPTION

In general, according to one embodiment, a template is to be inspected, which is directed for manufacturing a memory cell array including a relievable area and a redundant area replaceable with the relievable area. First, a decision is made as to whether a detected defect is positioned within a relievable area based on a defect position of a defect-detected template and position information on the relievable area. Then, a decision is made as to whether the number of defect-detected relievable areas exceeds the preset permissible number. When the detected defect is positioned outside the relievable area or when the number of defect-detected relievable areas exceeds the permissible number, a notification that the template has failed the inspection is output.

Exemplary embodiments of an inspecting method, a template manufacturing method, a semiconductor integrated circuit manufacturing method and an inspecting system will be explained below in detail with reference to the accompanying drawings. The present invention is not limited to the following embodiments.

When a defect occurs in a template, the defect is to be transferred onto a wafer. Thus, a template manufacturer has been required to manufacture defect-free templates in principle. One example (first comparative example) of the template manufacturing method until the delivery of templates is taken as a comparative example of a first embodiment of the present invention. According to the first comparative example, the template manufacturer manufactures a template, and inspects to confirm that a defect is not present on the manufactured template. When a defect is found by the inspection, the manufactured template is discarded as inspection-failed, and a next template is manufactured. When a defect is not found, the template is delivered as inspection-passed. As described above, a defect-free fine structure in nanometer scale is not easy to manufacture and thus the manufacture and the inspection are repeated until the inspection is passed. The delivery deadline and cost of the templates are prolonged and increased according to the number of repetitions.

On the other hand, when a failure due to incidentally-occurred pattern cutting or contact occurs in a memory cell array of a memory device formed on a wafer, a redundant circuit for replacing the failure with other circuit is typically applied. Thus, when a defect occurs in a memory cell array area replaceable with the redundant circuit, the memory cell array area can be relieved in a later step.

In the first embodiment of the present invention, when a position of an occurred defect is contained in the memory cell array area replaceable with the redundant circuit and a certain condition is met, the template is assumed as inspection-passed. Thus, the rate of inspection-pass is more increased than the first comparative example, and consequently the cost of templates can be reduced. Additionally, the delivery deadline of the templates can be reduced.

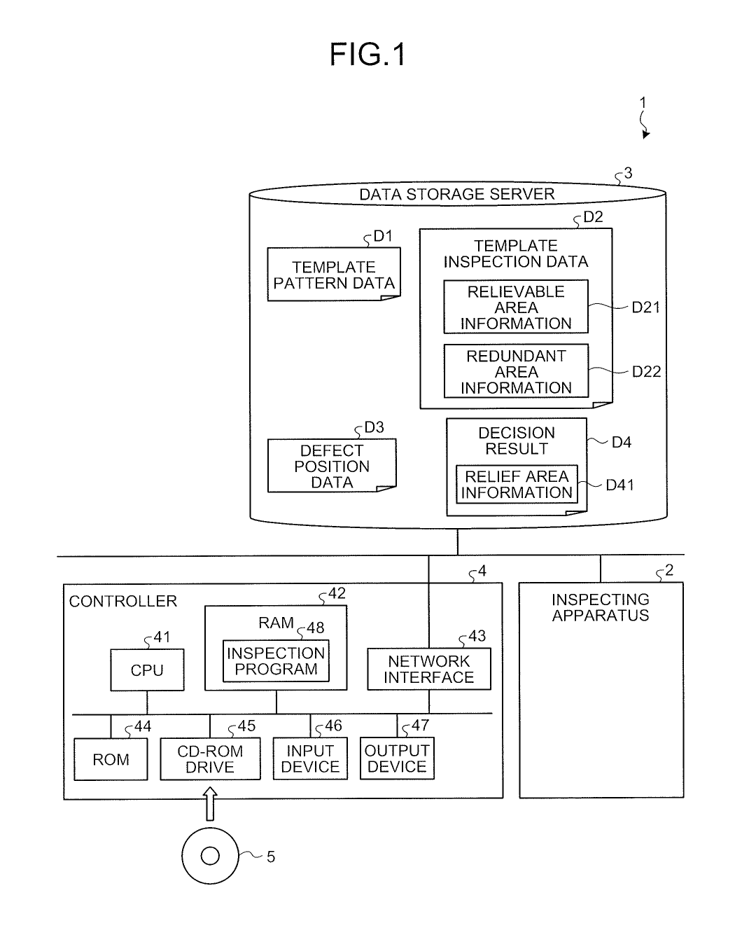

FIG. 1 is a diagram for explaining an exemplary structure of the inspecting system according to the first embodiment of the present invention. As illustrated, the inspecting system 1 includes an inspecting apparatus 2, a data storage server 3 and a controller 4. The inspecting apparatus 2, the data storage server 3 and the controller 4 are interconnected via a network such as Internet or Intranet.

The data storage server 3 stores therein various items of data used in the inspecting system 1, and previously stores therein template pattern layout data (template pattern data D1) and template inspection data D2 in an associated manner. The data storage server 3 stores therein defect position data D3 output by the inspecting apparatus 2 and decision results D4 output by the controller 4.

As described above, the memory cell array in the memory device includes a redundant circuit for replacing a defect part. Specifically, a control circuit for controlling the operations of a memory chip controls the operations per unit (relievable area) inside the memory cell array by addressing. When a condition under which a row or column including a defect part is selected is met due to the addressing, the control circuit stops selecting and driving the address, and selects and drives an address corresponding to the row or column of the memory cell array (redundant area) as the redundant circuit provided in another position inside the memory cell array.

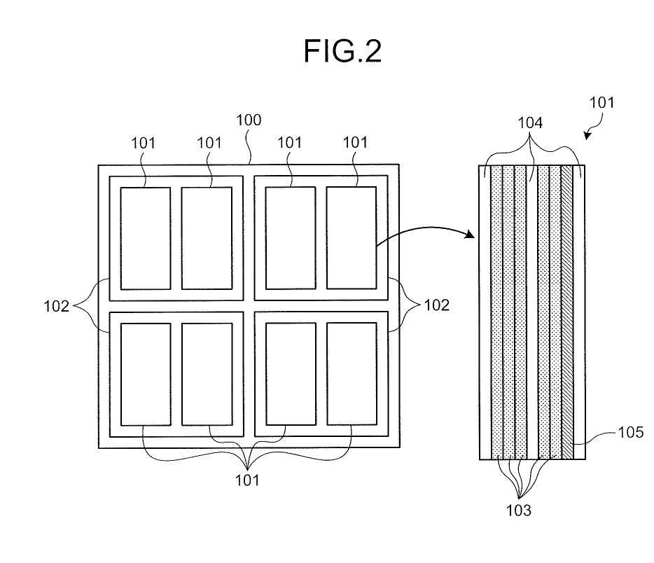

FIG. 2 is a diagram illustrating an exemplary template pattern. In a template pattern 100 in the example of FIG. 2, the pattern of memory chips 102 each having two memory cell arrays 101 is transferred with one pressing. The memory cell arrays 101 each include five relievable areas 103, three non-relievable areas 104 and a redundant area 105. The non-relievable area 104 corresponds to a peripheral circuit for accessing a memory cell array, such as row decoder or column decoder. When a defect is found one of the five relievable areas 103, the defect-occurred relievable area 103 is replaced with the redundant area 105. The numbers of relievable areas 103 and redundant areas 105 illustrated in FIG. 2 are merely exemplary and the memory cell array is increasingly highly integrated so that an actual memory cell array includes more relievable areas 103 and redundant areas 105 than illustrated in FIG. 2.

The template inspection data D2 contains information on the positions of the relievable areas (relievable area Information D21) and information on the positions of the redundant areas (redundant area information D22). The template pattern data D1 and the template inspection data D2 can be created by use of the method described in Japanese Patent Application Laid-Open No. 2008-129477 Publication, for example. The method for creating the template inspection data D2 will be briefly described below.

Design pattern data is described in a CAD (Computer Aided Design) format such as GDS. With the design pattern data employing the CAD format, the design patterns of the respective layers in the semiconductor integrated circuit made of a plurality of layers are described by use of one or more layers. One or more layers for one layer of pattern data contained in the design pattern data are combined to obtain layer combination data per layer configuring the semiconductor integrated circuit. The cell array patterns of the respective memory cells are extracted from the layer combination data of each layer. The cell array patterns are extracted with reference to each layer information contained in the template pattern data D1, the layer combination data, and circuit connection information. Each layer combination data is converted to obtain the template pattern data D1 per layer. Further, the relievable areas and the redundant areas are extracted from the extracted cell array patterns and the position information on the extracted relievable areas and redundant areas is calculated so that the template inspection data D2 per layer is obtained.

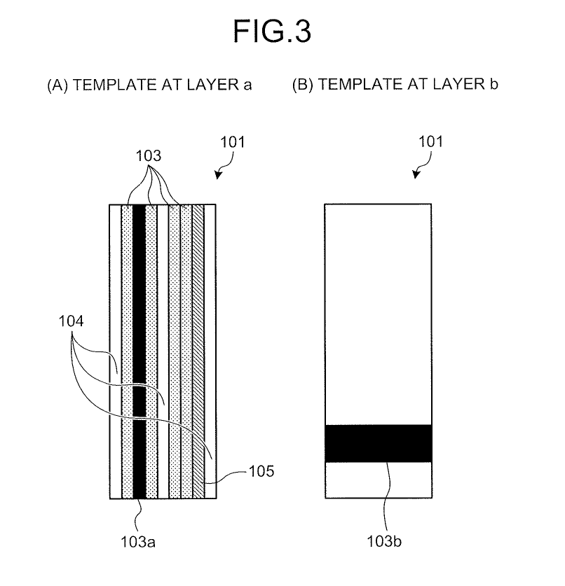

The circuit contained in one relievable area is not necessarily at the same position in each layer. FIG. 3 is diagrams for explaining one exemplary correspondence of relievable areas between the layers. In the example of FIG. 3, a relievable area having the function of operating the relievable area 103a at the layer a corresponds to 103b at the layer b. In other words, when the relievable area 103a is relieved, the relievable area 103b at the layer b is relieved. It is assumed that the relievable areas in the layers described in the template inspection data D2 used in the first embodiment correspond to each other in terms of the function beyond the layers as the correspondence between the relievable area 103a and the relievable area 103b.

Specifically, the template inspection data D2 may be data in which the range of the relievable area and the range of the redundant area are described in coordinates or may be data in which the ranges of the respective areas are indicated in a bitmap form.

The format of the template pattern data D1 may employ the GDS format, for example. A new layer is added to the template pattern data D1 and the template inspection data D2 is described in the added layer so that the template pattern data D1 may be corresponded to the template inspection data D2.

The inspecting apparatus 2 captures a SEM (Scanning Electron Microscope) image of a wafer on which a template pattern to be inspected is transferred, and creates defect position data D3 describing the position of the defect occurred on the template based on the captured SEM image. The inspecting apparatus 2 stores the created defect position data D3 in the data storage server 3. The defect position data D3 may be text data describing defect coordinates, for example, or data indicating the defect coordinates in a bitmap form. The inspecting apparatus 2 may directly capture the pattern on the template to be inspected and create the defect position data D3 based on the captured image. The inspecting apparatus 2 may capture a microscopic-optical image instead of the SEM image and create the defect position data D3 based on the captured image. The inspecting apparatus 2 may create the defect position data D3 based on a comparison between the captured image of the resist pattern formed on the wafer or the template pattern formed on the template and the template pattern data D1, for example.

The controller 4 calculates the number of defect-occurred relievable areas 103 based on the template inspection data D2 and the defect position data D3, and when the calculated number does not exceed the permissible number, the template is considered as inspection-passed, and when the calculated number exceeds the permissible number, the template is considered as inspection-failed. The permissible number is set in consideration of the comparison between the number of redundant areas and the number of relievable areas, the rate of defect occurrence in a later step such as wafer manufacturing step, and the delivery deadline and cost of the template. As the set permissible number is larger, the number of redundant areas usable when a new defect occurs in a later step is less, but the rate of inspection-pass of the templates can be increased and the delivery deadline and cost can be further reduced.

The controller 4 is configured similar to a typical computer to have a CPU (Central Processing Unit) 41, a RAM (Random Access Memory) 42, a network interface 43, a ROM (Read Only Memory) 44, a CD-ROM drive 45, an input device 46 and an output device 47. The CPU 41, the RAM 42, the network interface 43, the ROM 44, the CD-ROM drive 45, the input device 46 and the output device 47 are interconnected via a bus line.

The CPU 41 executes an inspection program 48 as computer program for deciding whether the template has passed or failed the inspection. The input device 46 includes a mouse and a keyboard, and is input the operations of the controller 4 by an operator. The operation information input into the input device 46 is sent to the CPU 41.

The inspection program 48 is stored in the ROM 44 and is loaded to the RAM 42 via the bus line. The CPU 41 executes the inspection program 48 loaded in the RAM 42. The CPU 41 executes the inspection program 48 developed in the RAM 42 to decide whether the template has passed or failed the inspection, and generates a decision result D4 to store the decision result D4 in the data storage server 3 in association with the template pattern data D1.

The output device 47 is a display device such as liquid crystal monitor, which displays output information for the operator, such as the operation screen or the contents of the decision result D4, based on the instruction from the CPU 41. The network interface 43 is a connection interface for connecting to the network to which the data storage server 3 and the inspecting apparatus 2 are connected. The CD-ROM drive 45 is a readout device for reading a CD-ROM 5 as a computer-readable recording medium.

The inspection program 48 executed by the controller 4 may be stored on the computer connected to the network such as Internet and may be downloaded via the network to be provided or distributed. The inspection program 48 may be provided or distributed via the network such as Internet. The inspection program 48 may be previously incorporated in the ROM 44 or the like to be provided to the controller 4. The inspection program 48 may be recorded in the recording medium such as the CD-ROM 5 to be provided or distributed. The inspection program 48 recorded in the CD-ROM 5 is read by the CPU 41 via the CD-ROM drive 45 and is developed in the RAM 42.

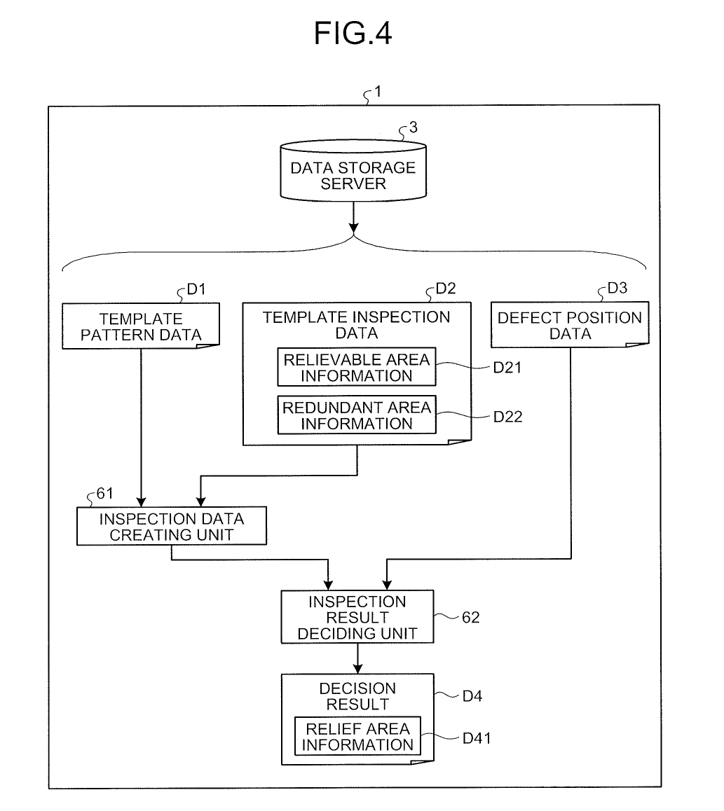

FIG. 4 is a diagram for explaining a functional structure of the inspecting system 1 according to the first embodiment. As illustrated, the inspecting system 1 includes an inspection data creating unit 61 and an inspection result deciding unit 62. The controller 4 executes the inspection program 48 so that the two structure elements are generated on the RAM 42.

The inspection data creating unit 61 acquires the template pattern data D1 and the template inspection data D2 from the data storage server 3, converts the template pattern described in the template pattern data D1 into a resist pattern, and converts the position information on the relievable areas 103 indicated in the relievable area information D21 into the resist pattern in a corresponding manner.

The inspection result deciding unit 62 decides whether the template has passed or failed the inspection based on the converted position information on the relievable areas 103. When a defect occurs in a template and the template is decided as inspection-passed, the inspection result deciding unit 62 outputs the decision result D4 attached with the relief area information D41 as the position information on the defect-occurred relievable areas 103.

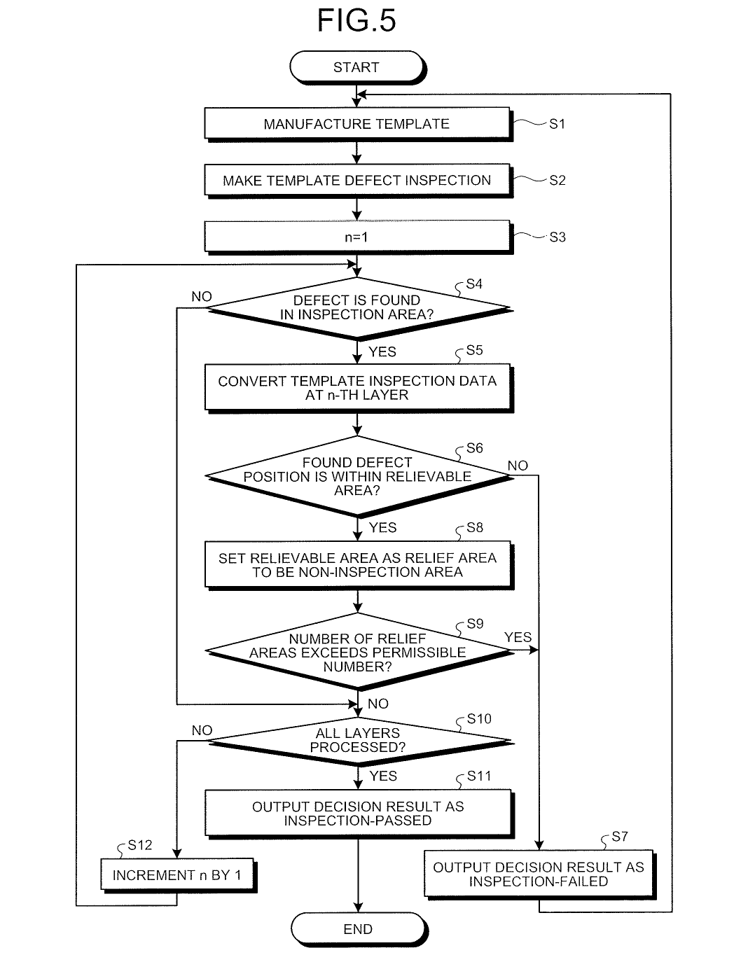

FIG. 5 is a flowchart for explaining the method for manufacturing a template by use of the inspecting system 1 according to the first embodiment. As illustrated, a template manufacturer first manufactures a template (step S1) and uses the inspecting apparatus 2 to make a defect inspection on the manufactured template (step S2). When making the defect inspection, the inspecting apparatus 2 outputs the defect position data D3 and stores it in the data storage server 3.

The controller 4 assumes that the variable n used in the subsequent repeated processings is 1 (step S3), and the inspection result deciding unit 62 refers to the defect position data D3 and decides whether a defect has been detected in an area to be inspected (inspection area) in the template at the n-th layer out of the layers configuring the semiconductor integrated circuit (step S4). In step S8 described later, a non-inspection area is set within the area where the pattern is formed. The inspection area refers to a pattern-formed area excluding a non-inspection area.

When a defect is detected (step S4, Yes), the inspection data creating unit 61 converts the position information on the relievable area at the n-th layer in the template inspection data D2 (step S5) and the inspection result deciding unit 62 compares the converted position information with the defect position data D3 so that a decision is made as to whether the detected defect is within the relievable area 103 (step S6). When a defect is positioned outside the relievable area 103 (step S6, No), the non-relievable defect is to be transferred to all the wafers and thus the inspection result deciding unit 62 outputs the decision result D4 as inspection-failed (step S7). When confirming the decision result D4 as inspection-failed, the template manufacturer proceeds to step S1 and creates a new template again.

When the detected defect is within the relievable area (step S6, Yes), the inspection result deciding unit 62 sets the defect-detected relievable area 103 as the relief area to be relieved with the redundant area 105 and sets the relief area as non-inspection area (step S8). The area newly set as non-inspection area (relief area) in the processing at each layer is merged to the area set as the non-inspection area (relief area) in the processings up to the previous layer and the merged area is to be the non-inspection area (relief area) when the processing is performed on the next layer. The position of the non-inspection area in the processing at each layer changes depending on a functional relationship of the relievable areas between the layers. For example, when the relievable area 103a at the layer a illustrated in FIG. 3 is set as non-inspection area (relief area), the relievable area 103b during the processing at the layer b is to be a non-inspection area (relief area).

After step S8, the inspection result deciding unit 62 decides whether the number of relievable areas exceeds the preset permissible number (step S9), and when the number of relievable areas exceeds the permissible number (step S9, Yes), proceeds to step S7 to output the decision result D4 as inspection-failed. The relief area information D41 may not be attached to the decision result D4 as inspection-failed. When the number of relief areas does not exceed the permissible number (step S9, No), the inspection result deciding unit 62 decides whether the processings on the templates at all the layers configuring the semiconductor integrated circuit have been completed (step S10), and the processings on all the layers have not been completed (step S10, No), increments n by 1 to proceed to step S4.

When the processing on all the layers have been completed (step S10, Yes), the inspection result deciding unit 62 outputs the decision result D4 as inspection-passed attached with the position information on the relief areas (step S11) so that the manufacture of the template is completed. The inspection result deciding unit 62 describes the position information on the area set as relief area in step S10, Yes in the relief area information D41 and attaches it to the decision result D4. The template manufacturer may deliver the manufactured templates to the semiconductor manufacturer together with the decision result D4 as inspection-passed. The semiconductor integrated circuit manufacturer can relieve the relievable area 103 specified by the relief area information D41 with the redundant area 105 in the semiconductor integrated circuit manufacturing step.

In this way, according to the first embodiment of the present invention, a decision is made as to whether a defect is within a relievable area based on the defect position data D3 describing the defect position detected on the template and the relievable area information D21 (step S4, step S6), a decision is made as to whether the number of defect-detected relievable areas exceeds the preset permissible number (step S9), and when the defect is outside the relievable area (step S6, No) or when the number of defect-detected relievable areas exceeds the permissible number (step S9, Yes), a notification that the template has failed the inspection is output (step S7) so that the condition under which the template fails the inspection is alleviated as compared with the first comparative example and thus the templates can be manufactured at low cost, thereby consequently performing nanoimprinting at low cost. The delivery deadline for manufacturing the templates can be shortened.

Since when a defect-occurred relievable area is set as relief area (step S8) and the relief area is already set in the template at other layer configuring the same memory cell array in step S4, the relievable area corresponding to the relief area is assumed as non-inspection area, the area already set as relief area is not inspected redundantly at each template and a time to inspect a series of templates is shortened, thereby further shortening the delivery deadline of the templates.

Since when the template at each layer configuring the same memory cell array does not fail the inspection (step S10, Yes), the decision result D4 as inspection-passed is output together with the relief area information D41 (step S11), the semiconductor integrated circuit manufacturer can decide which relievable area is to be relieved based on the relief area information D41.

There has been described above that the inspecting apparatus 2 creates the defect position data D3, but the inspecting apparatus 2 may capture the SEM image and the controller 4 may create the defect position data D3 based on the captured SEM image. The controller 4 may be incorporated in the inspecting apparatus 2. A data storage device such as hard disk may be provided in the controller 4 or the inspecting apparatus 2 and the data storage device may be used as the data storage server 3.

There has been described above that a decision is made as to whether the template has passed or failed the inspection after completing the defect inspection on all the layers, but the decision may be made as to whether the template has passed or failed the inspection each time the defect inspection per layer is completed. After completing the decision as to whether the templates up to the i-th layer have passed or failed the inspection, the controller 4 notifies the inspecting apparatus 2 of the non-inspection areas on the template at the i+1-th layer and the inspecting apparatus 2 may not make the defect inspection on the notified non-inspection areas. Thereby, a time to make the defect inspection by the inspecting apparatus 2 can be shortened.

In order to reduce the cost of the templates, the template manufacturer duplicates the templates based on the inspection-passed template, and the semiconductor integrated circuit manufacturer uses the duplicated templates to manufacture the semiconductor integrated circuit. The source template to be duplicated may be called parent template and the templates duplicated from the parent template may be called child template.

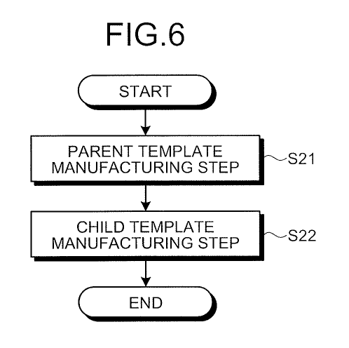

FIG. 6 is a flowchart for explaining a template manufacturing method according to a second embodiment. As illustrated, a parent template is first manufactured (step S21). The parent template manufacturing steps are similar to those in the first embodiment. Subsequently, child templates based on the inspection-passed parent template are manufactured (step S22).

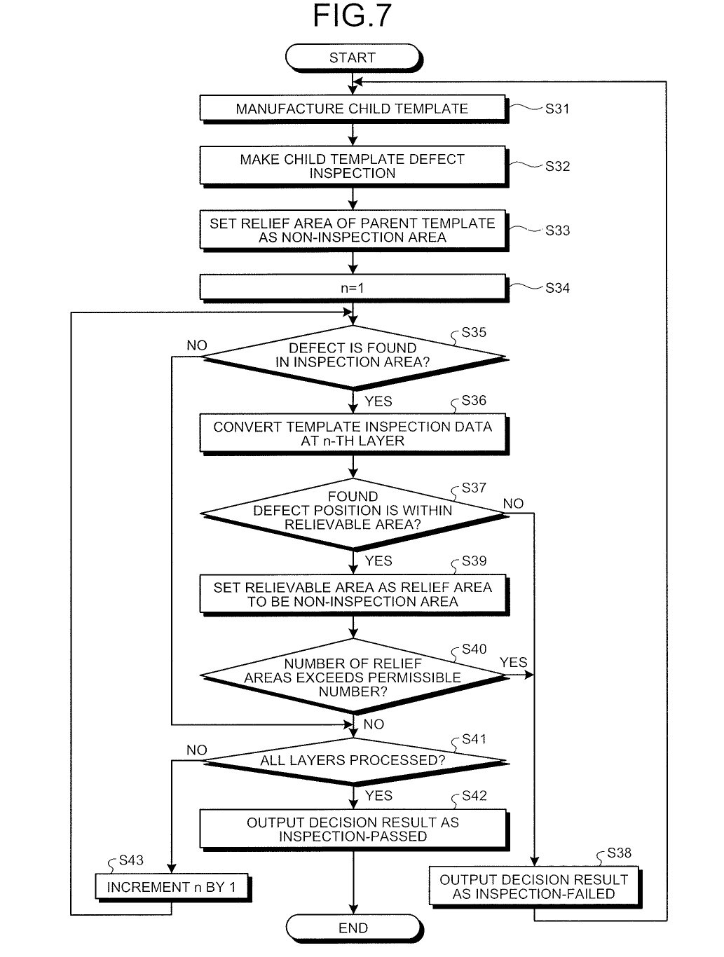

FIG. 7 is a flowchart for explaining the child template manufacturing steps. As illustrated, the template manufacturer first duplicates the inspection-passed parent template to manufacture the child templates (step S31). Then, the inspecting apparatus 2 is used to make the defect inspection on the manufactured child templates (step S32). When making the defect inspection, the inspecting apparatus 2 outputs the defect position data D3 and stores it in the data storage server 3.

In the controller 4, the inspection result deciding unit 62 acquires the inspection result D4 on the parent template and sets the relief area D41 attached to the decision result D4 as non-inspection area (step S33). After step S33, in step S34 to step S43, the processings similar to those in steps S3 to S11 illustrated in FIG. 5 are performed.

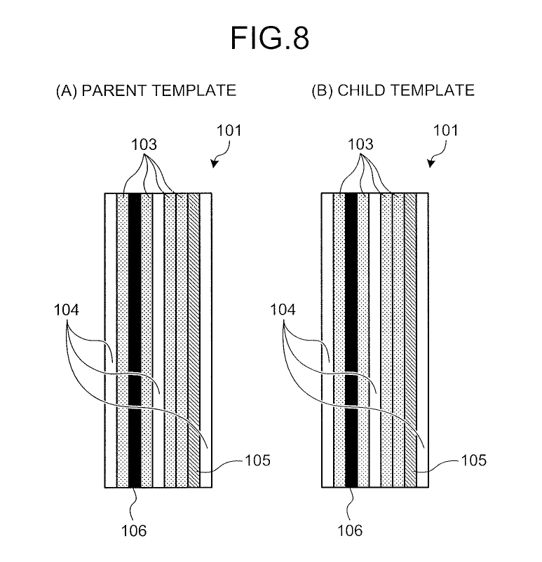

FIG. 8 is a diagram for explaining various areas of a parent template and a child template. As illustrated, when a relief area 106 is set in the parent template, the relief area 106 in the child template duplicated from the parent template is set as non-inspection area 106, and even when a new defect occurs in the non-inspection area 106, the defect is not considered when deciding whether the template has passed or failed the inspection.

As described above, according to the second embodiment of the present invention, when a template to be decided is duplicated (child template) from template (parent template) in a set of templates for the same memory cell array to which the notification as inspection-passed has been already output, the relievable area corresponding to the relief area set in the parent template is assumed as non-inspection area based on the relief area information D41 for the set of the parent template (step S33) and thus the cost for manufacturing the child templates can be reduced like the parent template. The delivery deadline of the child templates can be shortened.

When the template is separated from the hardened resist, the template can be broken due to a physical force on the template. When a defect occurs due to the broken template in the transferring step, the defect is subsequently transferred to all the wafers and the defect is to always occur at the same position (the defect will be referred to as repeat defect below). When there is configured such that if a template is broken by the occurrence of a repeat defect, the template is replaced, the rate of replacing the individual templates increases, which consequently leads an increase in the cost for manufacturing a semiconductor integrated circuit. Thus, according to the third embodiment, when the defect-occurred position is within the relievable area and a certain condition is met, the template can be continuously used without being discarded in order to relieve the defect-occurred relievable area with the redundant area.

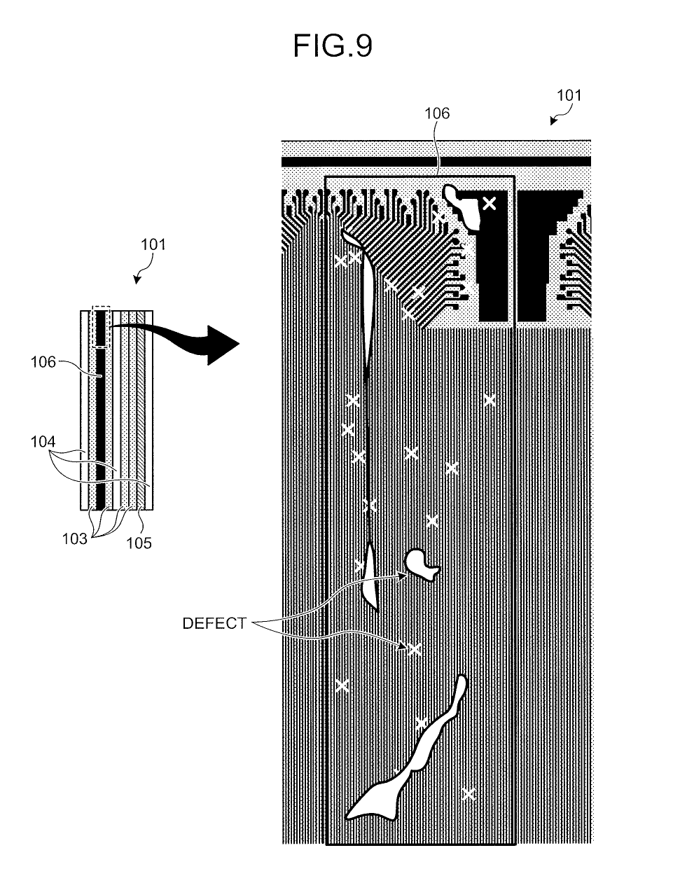

At present, the wafer defect managing method employs a method (second comparative example) for evaluating the condition of a wafer based on the number of occurred defects (or the rate of occurrence of defects per unit area). According to the second comparative example, when the number of occurred defects is a predetermined threshold or more, the wafer is decided as failure. FIG. 9 is diagrams for explaining a part set as relief area (non-inspection area). As illustrated in the right of FIG. 9, many defects occur on the wafer and the defects are contained in the relievable area 103 according to the third embodiment. The relievable area 103 is set as the relief area 106. With the second comparative example not the third embodiment, the number of defects on the wafer may exceed the threshold and the wafer may be decided as failure. However, according to the third embodiment, once a part is set as the relief area 106, however many defects occur in the part, the occurred defects are not taken into account and thus the number of defective wafers can be reduced.

A hardware structure of an inspecting system according to the third embodiment is similar to that of the first embodiment and thus an explanation thereof will be omitted herein. Numeral 7 is denoted to the inspecting system according to the third embodiment to be discriminated from the first embodiment. The data storage server 3 stores therein the decision result D4 on the templates manufactured by the template manufacturer. For example, when a child template is used for transfer, the decision result D4 on the child template is stored in the data storage server 3.

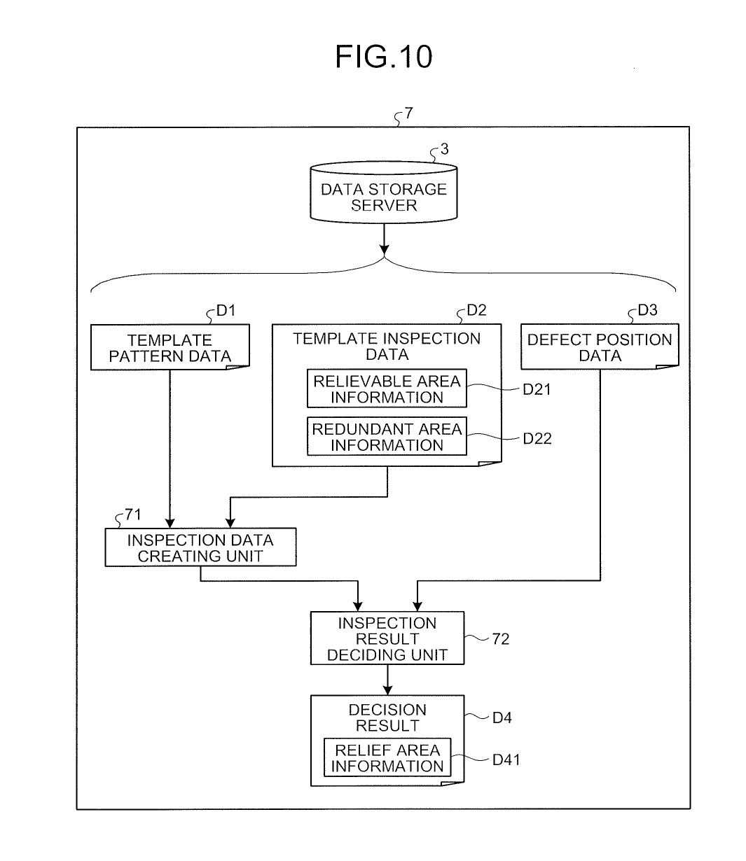

FIG. 10 is a diagram for explaining a functional structure of the inspecting system 7 according to the third embodiment. As illustrated, the inspecting system 7 includes an inspection data creating unit 71 and an inspection result deciding unit 72. The inspection data creating unit 71 acquires the template pattern data D1 and the template inspection data D2 from the data storage server 3, converts the template pattern described in the template pattern data D1 into a resist pattern, and converts the position information on the relievable area 103 and the redundant area 105 into the resist pattern in an associated manner. The inspection result deciding unit 72 decides whether to discard or keep using the template based on the converted relievable area 103. When it is decided that the template is kept using, the inspection result deciding unit 72 updates the relief area information D41 and sets the relievable area 103 in which a new defect occurs as new relief area.

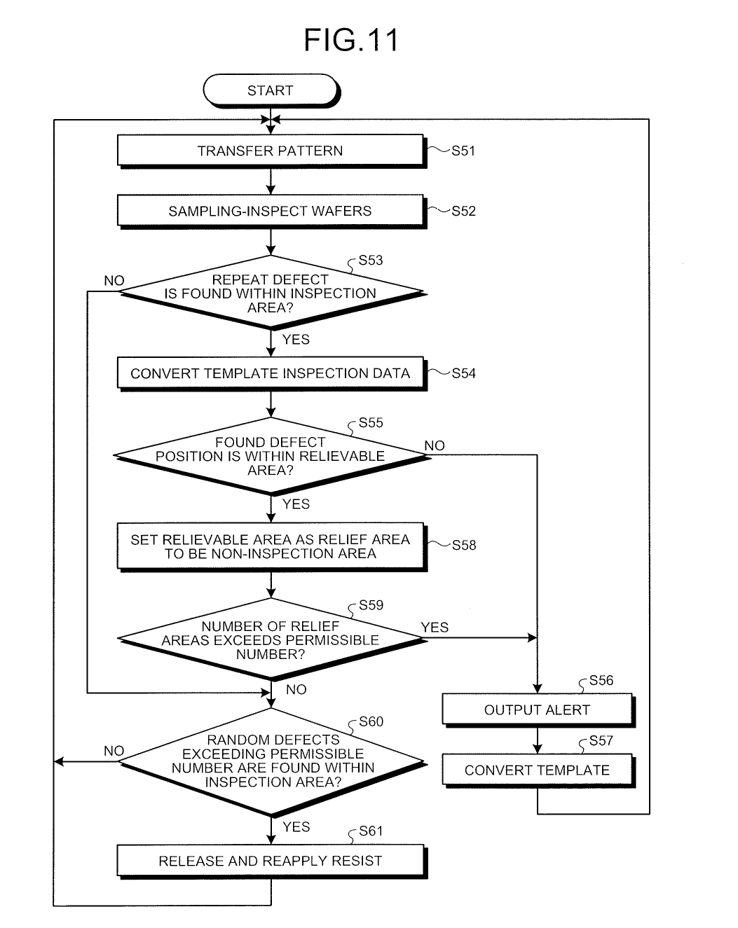

FIG. 11 is a flowchart for explaining a semiconductor integrated circuit manufacturing method according to the third embodiment. As illustrated, the semiconductor integrated circuit manufacturer uses the manufactured template to transfer the pattern onto the resist applied on the wafer (step S51). The pattern-transferred wafers are sampled at a predetermined timing and the inspecting apparatus 2 is used to make the defect inspection on the sampled wafers (step S52). Some wafers are subjected to sampling herein, but all the wafers may be inspected. When making the defect inspection, the inspecting apparatus 2 outputs the defect position data D3 and stores it in the data storage server 3.

In the controller 4, the inspection result deciding unit 72 refers to the defect position data D3 and decides whether a repeat defect has been detected within the inspection area at the layer (step S53). The repeat defect can be detected by comparing the defect position data D3 between dies, for example. When a repeat defect is not detected (step S53, No), the processing proceeds to step S60 described later.

When a repeat defect has been detected (step S53, Yes), the inspection data creating unit 71 converts the template inspection data D2 at the layer (step S54), and the inspection result deciding unit 72 compares the converted position information with the defect position data D3 thereby to decide whether the detected repeat defect is positioned within the relievable area 103 (step S55). When the defect is present outside the relievable area 103 (that is, within the non-relievable area 104) (step S55, No), the inspection result deciding unit 72 outputs an alert for promoting the replacement of the template (step S56). The semiconductor integrated circuit manufacturer confirming the alert replaces the template (step S57) and then proceeds to step S51 to perform pattern transfer on a new template.

When the found repeat defect is positioned within the relievable area 103 (step S55, Yes), the inspection result deciding unit 72 sets the relievable area 103 in which the repeat defect is detected as the relief area to be relieved with the redundant area 105, and sets the relief area as a new non-inspection area (step S58). The inspection result deciding unit 72 decides whether the number of relief areas exceeds the preset permissible number (step S59), and when the number of relief areas exceeds the permissible number (step S59, Yes), proceeds to step S56.

The repeat defect may occur due to some causes other than broken template. For example, when a particle occurring during the transferring step is attached on a template, the defect due to the particle subsequently appears as a repeat defect on a wafer. When a repeat defect has occurred due to a recoverable cause other than a broken template, the semiconductor integrated circuit manufacturer may reuse the alerted and removed template instead of discarding it. For example, when confirming an alert for promoting the replacement of the template (step S56), the semiconductor integrated circuit manufacturer replaces the template, inspects and analyzes the alerted and removed template, and it is found that a repeat defect has occurred due to some causes other than a broken template, may remove the cause of the repeat defect by cleansing the removed template and reuse the template in step S51. In this way, a life of the template can be further prolonged. When using the same template again after output the alert, the semiconductor integrated circuit manufacturer may use the relief area information D41 at the time of delivery of the template, not the relief area information D41 at the time of alert of the template, for the initial setting of the non-inspection area. Alternatively, the relief area in which a repeat defect is cleansed and removed may be set as relievable area for the relief area information D41 at the time of alert, and may be used.

When the number of relief areas does not exceed the permissible number (step S59, No), the inspection result deciding unit 72 confirms the defect position data D3 and decides whether random defects exceeding the permissible number have occurred within the inspection area (step S60). The random defect refers to a defect which occurs at a random position due to a variation in process in the transferring step or particles occurring during the process. The permissible number of random defects is separately set from the permissible number of repeat defects.

When the number of random defects does not exceed the permissible number (step S60, No), the processing proceeds to step S51 without replacing the template, and the pattern transferring is performed onto another wafer. When random defects exceeding the permissible number have occurred (step S60, Yes), the semiconductor integrated circuit manufacturer releases the resist and applies a resist again (step S61), proceeds to step S51 without replacing the template, and performs the pattern transferring onto the reapplied resist.

In this way, according to the third embodiment, since there is configured such that the template pattern formed on the template is transferred onto the resist applied on the wafer (step S51), the defect inspection is made on the resist pattern to output the defect inspection data D3 (step S52), a decision is made as to whether a repeat defect is positioned within the relievable area based on the defect position data D3 and the relievable area information D21 (step S53, step S55), a decision is made as to whether the number of relievable areas in which a repeat defect is detected exceeds the preset permissible number (step S59), and when the repeat defect is positioned outside the relievable area (step S55, No) or when the number of relievable areas in which the repeat defect is detected exceeds the permissible number (step S59, Yes), an alert for promoting the replacement of template is output (step S56), the life of template can be prolonged and consequently the nanoimprinting can be performed at low cost.

Since when the relievable area in which the repeat defect has occurred is set as relief area (step S58) and the relief area has been already set in the wafer manufactured with the same template, the relievable area corresponding to the relief area is assumed as non-inspection area, the area already set as relief area is not inspected at each wafer redundantly so that a time to inspect the wafer can be reduced and consequently the delivery deadline of the semiconductor integrated circuit can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template inspecting method for manufacturing a memory cell array comprising a relievable area and a redundant area replaceable with the relievable area, the method comprising:
making a first decision, based on a defect position of a defect-detected template and position information on a relievable area, as to whether the detected defect is positioned within the relievable area;
making a second decision as to whether the number of defect-detected relievable areas exceeds the preset permissible number; and
when the detected defect is positioned outside the relievable area or when the number of defect-detected relievable areas exceeds the permissible number, outputting a notification indicating that the template has failed the inspection.

2. The inspecting method according to claim 1, further comprising:
setting the defect-occurred relievable area as a relief area to be replaced with the redundant area,
wherein in the first decision processing, when a relief area has been already set in a template at other layer configuring the same memory cell array, a relievable area corresponding to the relief area is not decided.

3. The inspecting method according to claim 2, further comprising:
when a template at every layer configuring the same memory cell array has not failed the inspection, outputting a notification indicating the templates have passed the inspection together with the position information on the relief area.

4. The inspecting method according to claim 3, wherein in the first decision processing, when a template to be decided is duplicated from one template contained in a set of templates for the same memory cell array for which a notification that the templates have passed the inspection has been already output, a relievable area corresponding to the relief area set in the set of templates is not decided based on the position information on the relief area in the set of templates.

5. A template manufacturing method for manufacturing a memory cell array comprising a relievable area and a redundant area replaceable with the relievable area by use of templates of the memory cell array, comprising:
manufacturing a template;
making a defect inspection on the manufactured template;
outputting a position of a defect detected by the defect inspection;
performing a first decision processing as to whether the detected defect is positioned within a relievable area based on the output defect position and position information on a relievable area;
performing a second decision processing as to whether the number of defect-detected relievable areas exceeds the preset permissible number; and
when the detected defect is positioned outside a relievable area or when the number of defect-detected relievable areas exceeds the permissible number, outputting a notification that the template has failed the inspection.

6. The template manufacturing method according to claim 5, further comprising:
setting the defect-occurred relievable area as a relief area to be replaced with the redundant area,
wherein in the first decision processing, when a relief area has been already set in a template at other layer configuring the same memory cell array, a relievable area corresponding to the relief area is not decided.

7. The template manufacturing method according to claim 6, further comprising:
when a template at every layer configuring the same memory cell array has not failed the inspection, outputting a notification that the templates have passed the inspection together with the position information on the relief area.

8. The template manufacturing method according to claim 7, wherein in the first decision processing, when a template to be decided is duplicated from one template contained in a set of templates for the same memory cell array for which a notification that the templates have passed the inspection has been already output, a relievable area corresponding to the relief area set in the set of templates is not decided based on the position information on the relief area in the set of templates.

9. The template manufacturing method according to claim 5, wherein when the defect inspection is made, if a relief area has been already set in a template at other layer configuring the same memory cell array, a relievable area corresponding to the relief area is not defect-inspected.

10. A semiconductor integrated circuit manufacturing method for manufacturing a memory cell array comprising a relievable area and a redundant area replaceable with the relievable area by use of templates, the method comprising:
transferring a template pattern formed on a template onto a resist applied on a wafer;
making a defect inspection on the resist pattern transferred on the resist;
outputting a position of a defect detected by the defect inspection;
performing a first decision processing, based on the output defect position and position information on a relievable area, as to whether a repeat defect has occurred within the relievable area;
performing a second decision processing as to whether the number of relievable areas in which a repeat defect has occurred exceeds the preset permissible number; and
when a repeat defect has occurred outside a relievable area or when the number of relievable areas in which a repeat defect has occurred exceeds the permissible number, outputting an alert for promoting the replacement of the template used for transferring onto the resist.

11. The semiconductor integrated circuit manufacturing method according to claim 10, further comprising:
setting a relievable area in which the repeat defect has occurred as a relief area to be replaced with the redundant area,
wherein in the first decision processing, when a relief area has been already set in a wafer manufactured by the same template, a relievable area corresponding to the relief area is not decided.

12. The semiconductor integrated circuit manufacturing method according to claim 10, further comprising:
deciding whether a random defect has occurred in an area to be decided in the first decision processing.

13. The semiconductor integrated circuit manufacturing method according to claim 10, further comprising:
sampling a wafer to be subjected to the defect inspection.

14. The semiconductor integrated circuit manufacturing method according to claim 10, comprising:
comparing the output defect positions between dies and thereby recognizing a repeat defect in the first decision processing.

15. A template inspecting system for manufacturing a memory cell array comprising a relievable area and a redundant area replaceable with the relievable area, the system comprising:
a defect inspecting unit for making a defect inspection on a template and outputting a position of the detected defect; and
a deciding unit for, based on the output defect position and position information on a relievable area, deciding whether the detected defect is positioned within the relievable area, deciding whether the number of defect-detected relievable areas exceeds the preset permissible number, and when the detected defect is positioned outside the relievable area or when the number of defect-detected relievable areas exceeds the permissible number, outputting a notification that the template has failed the inspection.
